(19) United States
(12) Patent Application Publication
(10) Pub. No.: US 2024/0128169 A1
(43) Pub. Date: Apr. 18, 2024

(54) SEMICONDUCTOR DEVICE

(71) Applicant: ROHM CO., LTD., Kyoto-shi (JP)

(72) Inventors: Hajime OKUDA, Kyoto-shi (JP); Yuto NISHIYAMA, Kyoto-shi (JP); Toru TAKUMA, Kyoto-shi, Kyoto (JP)

(21) Appl. No.: 18/533,721

(22) Filed: Dec. 8, 2023

Related U.S. Application Data
(63) Continuation of application No. PCT/JP2022/024140, filed on Jun. 16, 2022.

(30) Foreign Application Priority Data
Jul. 6, 2021 (JP) 2021-112383

(51) Int. Cl. H01L 23/495; H01L 23/31

(52) U.S. Cl. CPC H01L 23/49568; H01L 23/3135; H01L 23/4952; H01L 23/49562; H01L 23/49575

(57) ABSTRACT

A semiconductor device is configured to increase energy absorbed by an active clamp. The semiconductor device comprises a semiconductor element, a sealing resin, and a coating member. The semiconductor element includes a first electrode. The sealing resin covers the semiconductor element. The coating member is interposed between the first electrode and the sealing resin. The coating member contains a material with higher thermal conductivity than the sealing resin.

### TECHNICAL FIELD

The present disclosure relates to a semiconductor device.

### BACKGROUND ART

Switching elements are used to control the flow of current in various industrial equipment and automobiles. An example of a conventional switching element is disclosed in JP-A-2019-212930. In the switching element, the electromotive force due to the current interruption generates energy. The active clamp functions to cause such energy to be absorbed by the switching element.

### BRIEF DESCRIPTION OF THE DRAWINGS

FIG. 1 is a plan view of a semiconductor device according to a first embodiment of the present disclosure.

FIG. 2 is a plan view showing relevant parts of the semiconductor device according to the first embodiment of the present disclosure.

FIG. 3 is a circuit diagram of a semiconductor element in the semiconductor device according to the first embodiment of the present disclosure.

FIG. 4 is a front view of the semiconductor device according to the first embodiment of the present disclosure.

FIG. 5 is a side view of the semiconductor device according to the first embodiment of the present disclosure.

FIG. 6 is a cross-sectional view taken along lines V-V in FIG. 2.

FIG. 7 is a cross-sectional view taken along lines VI-VI in FIG. 2.

FIG. 8 is a partially enlarged cross-sectional view showing relevant parts of the semiconductor device according to the first embodiment of the present disclosure.

FIG. 9 is a partially enlarged cross-sectional view showing the relevant parts of the semiconductor device according to the first embodiment of the present disclosure.

FIG. 10 is a plan view showing a first variation of the semiconductor device according to the first embodiment of the present disclosure.

FIG. 11 is a plan view showing relevant parts of a semiconductor device according to a second embodiment of the present disclosure.

FIG. 12 is a plan view showing relevant parts of a semiconductor device according to a third embodiment of the present disclosure.

FIG. 13 is a cross-sectional view taken along lines XIII-XIII in FIG. 12.

FIG. 14 a cross-sectional view taken along lines XIV-XIV in FIG. 12.

FIG. 15 is a plan view showing relevant parts of a semiconductor device according to a fourth embodiment of the present disclosure.

FIG. 16 is a cross-sectional view taken along lines XVI-XVI in FIG. 15.

FIG. 17 is a plan view showing relevant parts of a semiconductor device according to a fifth embodiment of the present disclosure.

FIG. 18 is a cross-sectional view taken along lines XVIII-XVIII in FIG. 17.

FIG. 19 is a plan view showing relevant parts of a first variation of the semiconductor device according to the fifth embodiment of the present disclosure.

### DETAILED DESCRIPTION OF EMBODIMENTS

The following describes preferred embodiments of semiconductor devices of the present disclosure with reference to the drawings.

In the present disclosure, the terms “first,” “second,” “third,” etc. are used merely for the purpose of identification, and are not necessarily intended to order their objects.

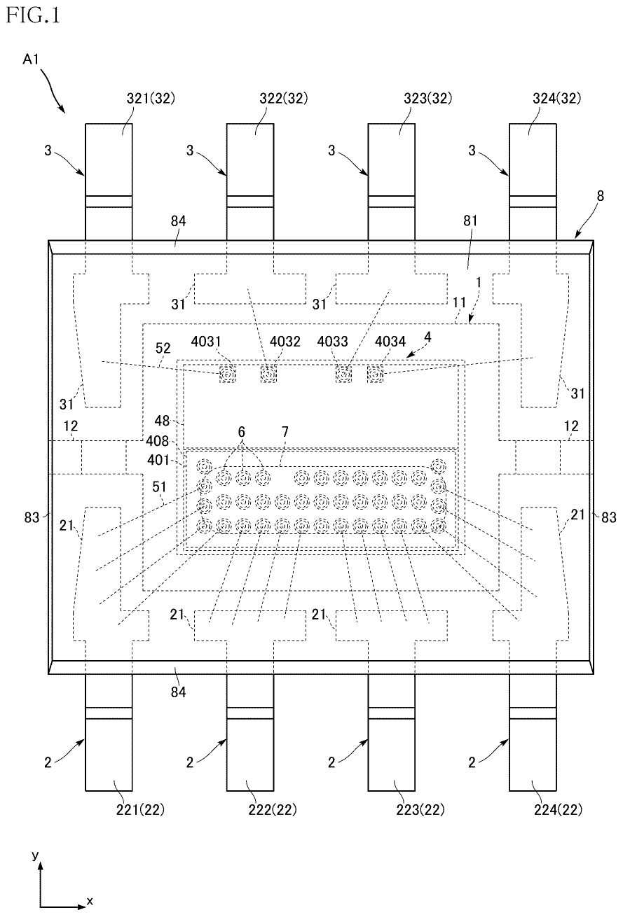

FIGS. 1 to 9 show a semiconductor device A1 according to a first embodiment of the present disclosure. The semiconductor device A1 includes a first lead 1, a plurality of second leads 2, a plurality of third leads 3, a semiconductor element 4, a plurality of first wires 51, a plurality of second wires 52, a plurality of metal lumps 6, a coating member 7, and a sealing resin 8. The shape and size of the semiconductor device A1 are not limited. In one example of the semiconductor device A1, the size in the x direction is about within 4 to 7 mm, the size in the y direction is about within 4 to 8 mm, and the size in the z direction is about within 0.7 to 2.0 mm.

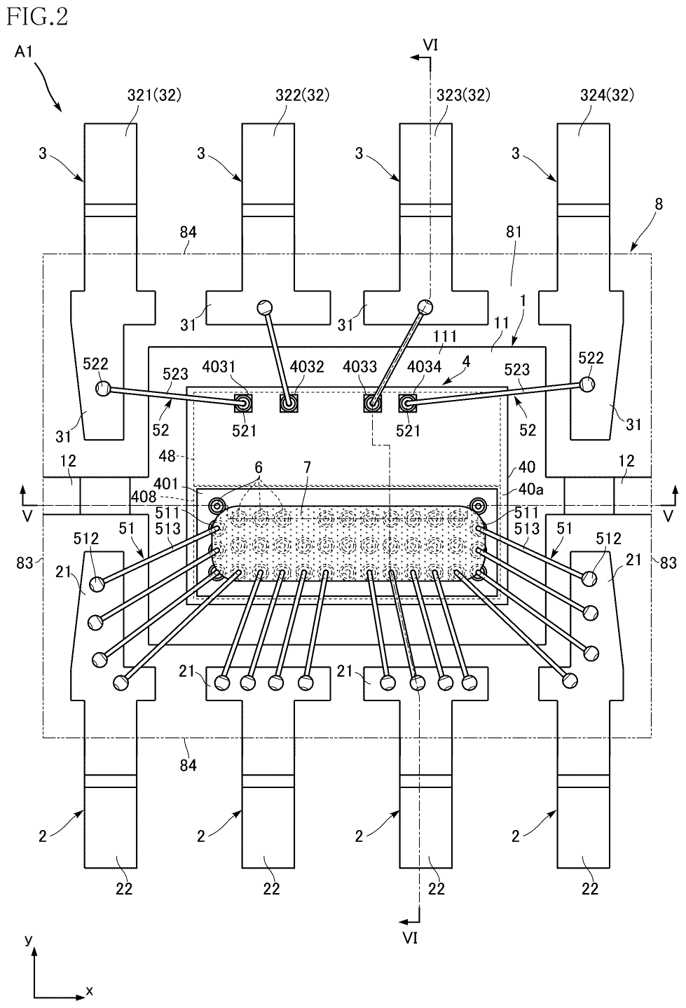

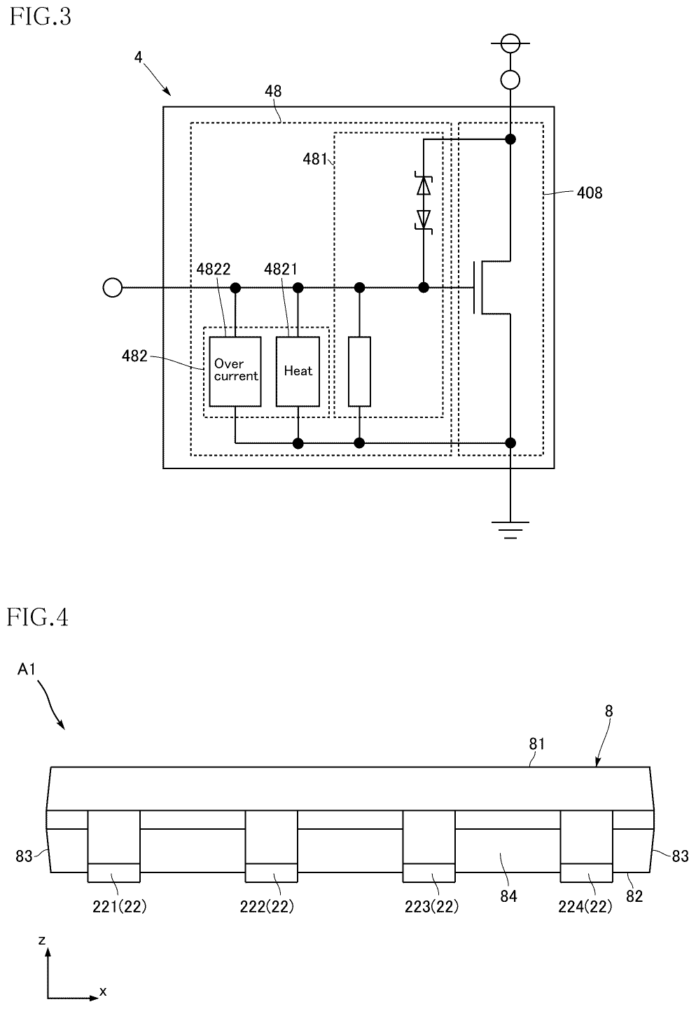

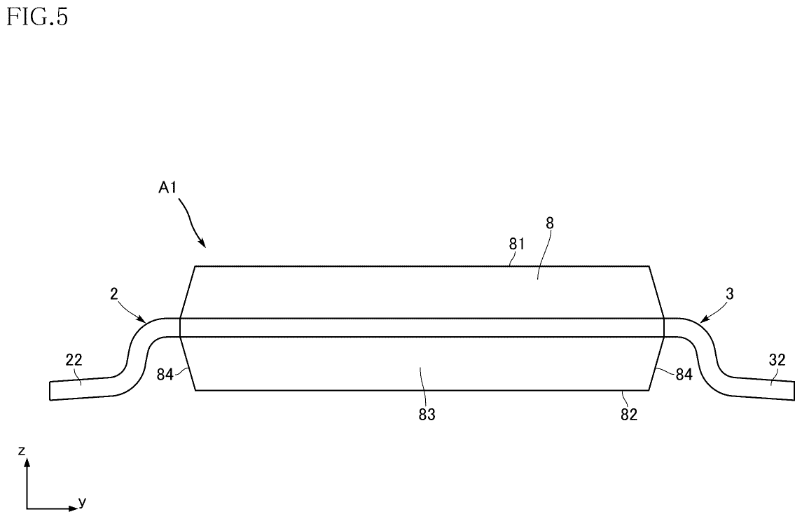

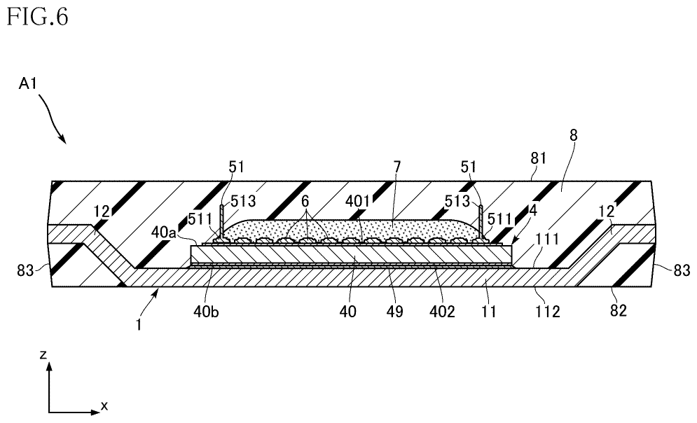

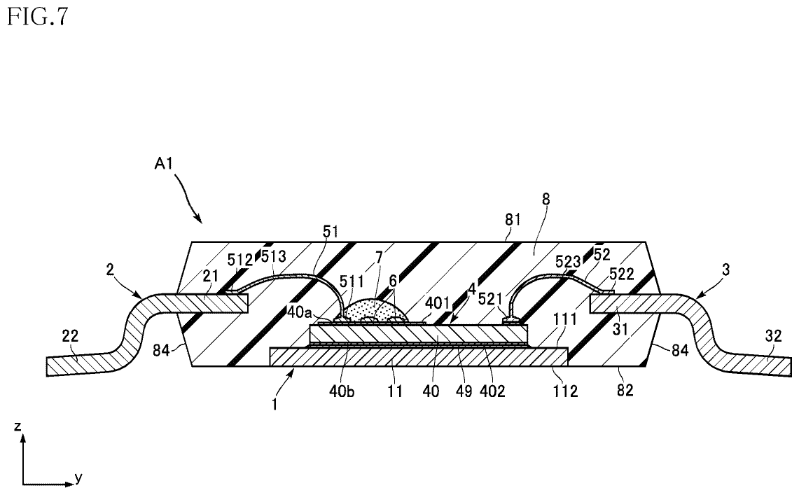

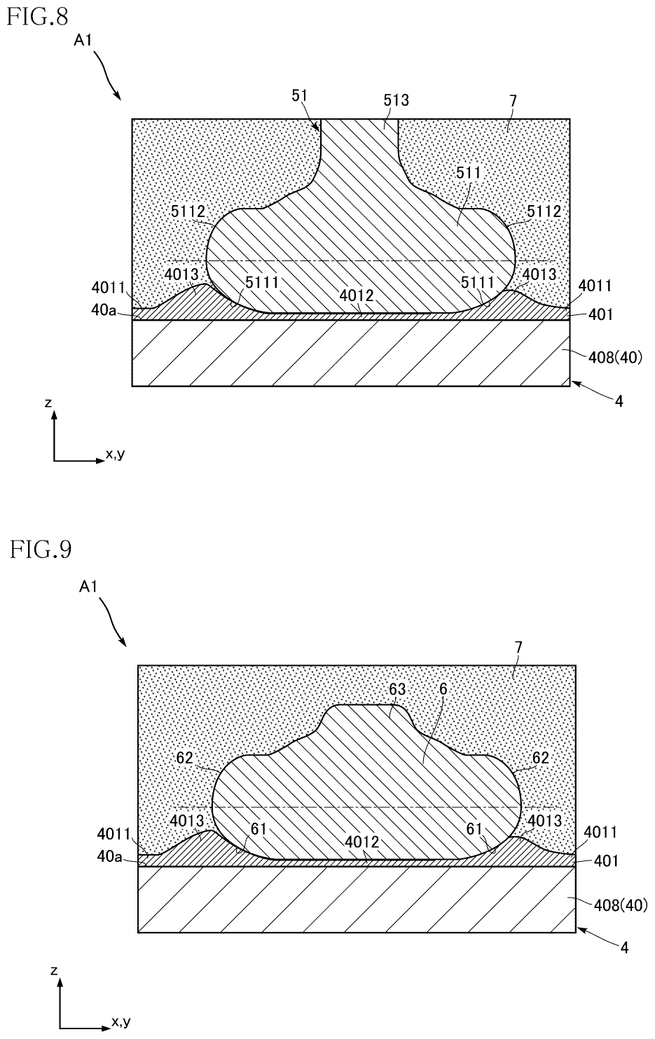

FIG. 1 is a plan view of the semiconductor device A1. FIG. 2 is a plan view showing relevant parts of the semiconductor device A1. FIG. 4 is a front view of the semiconductor device A1. FIG. 5 is a side view of the semiconductor device A1. FIG. 6 is a cross-sectional view taken along lines V-V in FIG. 2. FIG. 7 is a cross-sectional view taken along lines VI-VI in FIG. 2. FIG. 8 is a partially enlarged cross-sectional view showing relevant parts of the semiconductor device A1. FIG. 9 is a partially enlarged cross-sectional view showing relevant parts of the semiconductor device A1.

The first lead 1 supports the semiconductor element 4 and functions as an electrical conduction path to the semiconductor element 4. The material of the first lead 1 is not limited, and it may include a metal such as Cu, Ni, Fe, or may include an alloy containing these metals. The first lead 1 may be formed with a plating layer made of a metal such as Ag, Ni, Pd, Au etc., in an appropriate location. The thickness of the first lead 1 is not limited, and may be about within 0.12 to 0.2 mm, for example.

The first lead 1 of the present embodiment includes a die pad section 11 and two extending sections 12.

The die pad section 11 is a part supporting the semiconductor element 4. The shape of the die pad section 11 is not limited, and may be a rectangle as viewed in the z direction. The die pad section 11 has a die pad obverse face 111 and a die pad reverse face 112. The die pad obverse face 111 faces in the z direction. The die pad reverse face 112 faces opposite from the die pad obverse face 111 in the thickness direction. In the illustrated example, the die pad obverse face 111 and the die pad reverse face 112 are flat.

The two extending sections 12 are parts extending from the die pad section 11 to both sides of the x direction, respectively. In the present embodiment, each extending section 12 is bent as a whole, including a first part extending from the die pad portion 11 along the x direction, a second part inclined relative to the first part toward the side of the z direction in which the die pad obverse face 111 faces, and a third part extending from the second part along the x direction.

The second leads 2 are spaced apart from the first lead 1 and function as electrical conduction paths to the semiconductor element 4. In the present embodiment, the second leads 2 provide electrical conduction paths, through which an electrical current to be switched by the semiconductor element 4 flows. The second leads 2 are disposed in one side of the y direction with respect to the first lead 1. The second leads 2 are spaced apart from each other in the x direction.

The material of the second leads 2 is not limited, and it may include a metal, such as Cu, Ni, Fe, or may include an alloy containing these metals. Each second lead 2 may be formed with a plating layer made of a metal, such as Ag, Ni, Pd, Au etc., in an appropriate location. The thickness of each second lead 2 is not limited, and may be about within 0.12 to 0.2 mm, for example.

Each second lead 2 of the present embodiment includes a pad section 21 and a terminal section 22.

The pad section 21 is a part to which a relevant first wire(s) 51 is connected. In the present embodiment, in the z direction, the pad section 21 is located away from the die pad section 11 in the direction in which the die pad obverse face 111 faces.

The terminal section 22 is a strip-like part extending outwardly from the pad section 21 in the y direction. The terminal section 22 is bent as viewed in the x direction, with its front edge disposed generally at the same location as the die pad section 11 in the z direction. In the illustrated example, the terminal section 22 is a power supply terminal.

The third leads 3 are spaced apart from the first lead 1 and function as electrical conduction paths to the semiconductor element 4. In the present embodiment, the third leads 3 provide electrical conduction paths for a control signal current to control the semiconductor element 4. The third leads 3 are disposed on the other side of the first lead 1 in the y direction. The third leads 3 are spaced apart from each other in the x direction.

The material of the third leads 3 is not limited, and it may include a metal, such as Cu, Ni, Fe, or may include an alloy containing these metals. Each third lead 3 may be formed with a plating layer made of a metal, such as Ag, Ni, Pd, Au etc., in an appropriate location. The thickness of each third lead 3 is not limited, and may be about in a range of 0.12 to 0.2 mm, for example.

Each third lead 3 of the present embodiment includes a pad section 31 and a terminal section 32.

The pad section 31 is a part to which a relevant second wire(s) 52 is connected. In the present embodiment, in the z direction, the pad section 31 is located away from the die pad section 11 in the direction in which the die pad obverse face 111 faces.

The terminal section 32 is a strip-like part extending outwardly from the pad section 31 in the y direction. The terminal section 32 is bent as viewed in the x direction, with its front edge disposed at the same (or generally at the same) location as the die pad section 11 in the z direction.

As shown in FIG. 2, the terminal sections 32 of the third leads 3 are labeled as terminal sections 321, 322, 323, 324. The terminal section 321 is an output terminal electrically connected to the third electrode 4031 described later. The terminal section 322 is a ground terminal electrically connected to the third electrode 4032 described later. The terminal section 323 is a self-monitoring output terminal electrically connected to the third electrode 4033 described later. The terminal section 324 is an input terminal electrically connected to the third electrode 4034 described later.

In the semiconductor device A1, the semiconductor element 4 provides an electrical function. In the present embodiment, the semiconductor element 4 performs switching. The semiconductor element 4 includes an element body 40, a first electrode 401, a second electrode 402, and a plurality of third electrodes 403. The semiconductor element 4 includes a switching section 408 in which transistors are formed to perform switching, and a control section 48 for e.g., controlling, monitoring and protecting the transistors of the switching section 408. The control section 48 may include transistors of a horizontal structure type.

The element body 40 has an element obverse face 40a and an element reverse face 40b. In the z direction, the element obverse face 40a faces the same direction as the die pad obverse face 111. In the z direction, the element reverse face 40b faces opposite from the element obverse face 40a. The material of the element body 40 is not limited. For example, the element body 40 may be made of a semiconductor material, such as Si, SiC, GaN.

The element body 40 has the switching section 408. The switching section 408 is provided with a transistor structure, such as a MOSFET (Metal Oxide Semiconductor Field Effect Transistor) or a MISFET (Metal Insulator Semiconductor Field Effect Transistor). As shown in FIGS. 1 and 2, as viewed in the z direction, the switching section 408 and the control section 48 are arranged side by side in the y direction. However, the specific arrangement of the switching section 408 and the control section 48 is not limited.

The first electrode 401 is disposed on the element obverse face 40a. In the illustrated example, in the y direction, the first electrode 401 is disposed at the same location as the second leads 2 in the element obverse face 40a. As viewed in the z direction, the first electrode 401 overlaps with the switching section 408. In the present embodiment, as viewed in the z direction, the first electrode 401 is spaced apart from the control section 48. In the present embodiment, the first electrode 401 is a source electrode. The material of the first electrode 401 is not limited, and it may include a metal, such as Al (aluminum), Al-Si, Cu (cupper), or may include an alloy containing these metals. The first electrode 401 may have a lamination consisting of layers of different materials selected from these metals.

As shown in FIGS. 8 and 9, the first electrode 401 includes a base thickness section 4011, a reduced thickness section 4012, and a bulging section 4013. The base thickness section 4011 corresponds to most of the area of the first electrode 401 where the bonding sections 511 of the first wires 51 and the metal lumps 6 described later are not provided. The thickness of the base thickness section 4011, for example, corresponds to the thickness after a treatment, such as plating for forming the first electrode 401, is completed.

The reduced thickness section 4012 is a part of the first electrode 401 where either the bonding section 511 or the metal lump 6 is joined, and is thinner than the base thickness section 4011. The reduced thickness section 4012 is, for example, a thinned section resulting from the joining process of the bonding section 511 or the metal lump 6.

The bulging section 4013 is a part between the base thickness section 4011 and the reduced thickness section 4012. The bulging section 4013 surrounds the reduced thickness section 4012. The bulging section 4013 is thicker than the base thickness section 4011 and the reduced thickness section 4012.

The second electrode 402 is disposed on the element reverse face 40b of the element body 40. As viewed in the z direction, the second electrode 402 overlaps with the switching section 408 and the control section 48, and in the present embodiment, the second electrode 402 covers the entirety of the element reverse face 40b. In the present embodiment, the second electrode 402 is a drain electrode. The material of the second electrode 402 is not limited, and it may include a metal, such as Al (aluminum), Al-Si, Cu (cupper), or may include an alloy containing these metals. The second electrode 402 may have a lamination consisting of layers of different materials selected from these metals.

The specific configuration of the control section 48 is not limited. The control section 48 may include a current sensor circuit, a temperature sensor circuit, an overcurrent protection circuit, a thermal protection circuit, and a low-voltage malfunction prevention circuit.

The third electrodes 403 are disposed on the element obverse face 40a. In the illustrated example, in the y direction, the third electrodes 403 are disposed at the same location as the third leads 3 in the element obverse face 40a. As viewed in the z direction, the third electrodes 403 overlap with the control section 48. In the present embodiment, the third electrodes 403 mainly conduct to the control section 48. The number of the third electrodes 403 is not limited. The number of the third electrode 403 may be one. In the illustrated example, the semiconductor element 4 has four third electrodes 403.

In the illustrated example, the four third electrodes 403 include third electrodes 4031, 4032, 4033, 4034. The third electrode 4031 is an output electrode, whose output current is limited when the load is in a short state and current exceeds the overcurrent detection value. The third electrode 4032 is a ground electrode. The third electrode 4033 is a self-monitoring output electrode, whose potential varies depending on whether or not an overcurrent state or overheated state (or both) is detected. The third electrode 4034 is an input electrode, to which a pull-down resistor is connected internally.

FIG. 3 shows an example of the circuit in the switching section 408 and the control section 48. The switching section includes transistors. The control section 48 includes an energy absorption circuit 481 and a protection circuit 482. The energy absorption circuit 481 is a circuit configured to absorb electrical energy caused by e.g., transient voltage, including a Zener diode and a resistor. The protection circuit 482 is a circuit configured to protect the control section 48, including a heat protection section 4821 and an overcurrent protection section 4822.

The first wires 51 electrically connect the first electrode 401 of the semiconductor element 4 with the second leads 2. The material of the first wires 51 is not limited, and it may include a metal, such as Au, Cu, or Al. The metals included in the first wires 51 may be different from the metals included in the first electrode 401. Each first wire 51 includes a bonding section 511, a bonding section 512 and a loop section 513. The specific configuration of each first wire 51 is not limited. In the illustrated example, the first wires 51 are made of a material including Cu and are provided by a capillary, for example. In the present embodiment, an electrical current to be switched by the semiconductor element 4 flows through the first wires 51.

The semiconductor device according to the present disclosure is not limited to the configuration that the first wires 51 are joined to the first electrode 401. For example, a conductive member provided by a metal plate rather than the first wires 51 may be connected to the first electrode 401. Alternatively, use may be made of another electrode conducting to the first electrode 401 via a conductive path provided within the semiconductor element 4, and the conductive members such as the first wires 51 may be in contact with the electrode.

Each bonding section 511 conducts to the first electrode 401 of the semiconductor element 4, and is located at the position overlapping with the first electrode 401 as viewed in the z direction. In the present embodiment, each bonding section 511 is joined to the first electrode 401, corresponding to a so-called first bonding section.

As shown in FIG. 8, each bonding section 511 has a first face 5111 and a second face 5112. The first face 5111 and the second face 5112 are arranged along the z direction with the intervention of the maximum diameter portion of the bonding section 511 (the portion of the maximum dimension in a direction perpendicular to the z direction, such as the x direction and the y direction; see the portion intersecting the dashed line shown in FIG. 8).

The first face 5111 is inclined such that it is located further away from the center of the bonding section 511 in any direction perpendicular to the z direction, such as the x direction or the y direction, as it proceeds further away from the first electrode 401 in the z direction. In the illustrated example, the first face 5111 is a convex curved surface. The second face 5112 is located opposite to the first face 5111 with the maximum diameter portion sandwiched. In the illustrated example, the second face 5112 is a convex curved surface.

The bonding section 512 is a part joined to the pad section 21 of the relative second lead 2. The bonding section 512 corresponds to a so-called second bonding section.

The loop section 513 is connected to the bonding section 511 and the bonding section 512, and is, for example, bent as a whole.

In the illustrated example, the bonding sections 511 are arranged along the outer edge of the first electrode 401. More specifically, the bonding sections 511 are arranged along the three sides included in the outer edge of the element body 40. The bonding sections 511 are arranged in a single row extending along the outer edge of the first electrode 401.

The second wires 52 electrically connect the third electrodes 403 of the semiconductor element 4 with the third leads 3. The material of the second wires 52 is not limited, and it may include a metal, such as Au, Cu, or Al. Each second wire 52 includes a bonding section 521, a bonding section 522 and a loop section 523. The specific configuration of each second wire 52 is not limited. In the illustrated example, the second wires 52 are provided by a capillary, for example. In the present embodiment, an electrical current to control the semiconductor element 4 flows through the second wires 52. In the example shown in FIG. 2, one of the second wires 52 connects the third electrode 4031 with the pad section 31 of the third lead 3 having the terminal section 321. One of the second wires 52 connects the third electrode 4032 with the pad section 31 of the third lead 3 having the terminal section 322. One of the second wires 52 connects the third electrode 4033 with the pad section 31 of the third lead 3 having the terminal section 323. One of the second wires 52 connects the third electrode 4034 with the pad section 31 of the third lead 3 having the terminal section 324.

The bonding section 521 is bonded to the third electrode 403 of the semiconductor element 4. The bonding section 521 corresponds to a so-called first bonding section.

The bonding section 522 is bonded to the pad section 31 of the third lead 3. The bonding section 522 corresponds to a so-called second bonding section.

The loop section 523 is connected to the bonding section 521 and the bonding section 522, and is, for example, bent as a whole.

Each of the metal lumps 6 includes a metal and is bonded to the first electrode 401. The specific configuration of each metal lump 6 is not limited. In the present embodiment, each metal lump 6 has the same configuration as the bonding section 511 of the first wire 51. Specifically, the metal lumps 6 are provided by cutting the wire material after the bonding section 511 is formed in the formation process of the first wire 51 using a capillary. Each metal lump 6 according to the present embodiment includes Cu. The number of the metal lumps 6 is not limited, and may be one. The semiconductor device according to the present disclosure may be configured without the metal lumps 6.

The arrangement of the metal lumps 6 is not limited. In the illustrated example, the metal lumps 6 are arranged inward of the first electrode 401. In other words, the metal lumps 6 are opposite to the outer edge of the first electrode 401 with respect to the bonding sections 511. In addition, the metal lumps 6 are arranged in a matrix. Possible arrangements of the metal lumps 6 in a matrix include an arrangement of multiple intersecting rows along x and y directions, or a so-called staggered arrangement.

As shown in FIG. 9, the metal lump 6 includes a first face 61, a second face 62, and a projection 63. The first face 61 and the second face 62 are arranged vertically with a maximum diameter portion of the metal lump 6 (the portion having the maximum dimension in a direction perpendicular to the z direction, such as the x direction or the y direction; see the portion intersecting the dashed line shown in FIG. 9) sandwiched between them in the z direction.

The first face 61 is inclined such that it is located further away from the center of the metal lump 6 in any direction perpendicular to the z direction, such as the x direction or the y direction, as it proceeds further away from the first electrode 401 in the z direction. In the illustrated example, the first face 61 is a convex curved surface. The second face 62 is located opposite to the first face 61 with the maximum diameter portion sandwiched. In the illustrated example, the second face 62 is a convex curved surface.

The projection 63 is a part protruding from the second face 62 to the opposite side of the first electrode 401 in the z direction. In the present example, the projection 63 results from cutting the wire material to provide the metal lump 6.

The coating member 7 is interposed between the first electrode 401 and the sealing resin 8. The coating member 7 contains a material with higher thermal conductivity than the sealing resin 8. The material of the coating member 7 is not limited, and it may include a metal in the case that the sealing resin 8 is made of an insulating resin. The coating member 7 may contain a metal different from the metal contained in the first electrode 401. A metal for providing the coating member 7 may be e.g., Ag or Cu. In an embodiment, the coating member 7 may contain sintered Ag or sintered Cu. When sintered Ag is contained in the coating member 7, preferably use may be made of a type of sintered Ag that can be formed without pressure. In the case the coating member 7 is made of sintered Ag formable without pressure, the coating member 7 may be formed by emitting from a nozzle the material paste, which will be the sintered Ag, and then heating the applied material paste in an appropriate manner.

The material of the coating member 7 is not limited to a metal. For instance, it may contain a resin with higher thermal conductivity than the insulating resin forming the sealing resin 8. In the case that the sealing resin 8 is made of epoxy resin, the constituent resin of the coating member 7 may include e.g., PC (polycarbonate), PA6 (nylon 6), PPS (polyphenylene sulfide), PBT (polybutylene terephthalate). For the coating member 7, these resins may be mixed with fillers to increase thermal conductivity.

In the present example, the coating member 7 contains sintered Ag, and is in contact with both of the first electrode 401 and the sealing resin 8. As viewed in the z direction, the coating member 7 is disposed inward of the outer edge of the first electrode 401.

In the present example, the coating member 7 is in contact with at least one of the metal lumps 6. The coating member 7 is also in contact with at least one of the bonding sections 511 of the first wires 51. In the illustrated example, the coating member 7 covers most of the metal lumps 6. In the illustrated example, the coating member 7 also covers most of the bonding sections 511 of the first wires 51. As shown in FIG. 2, the coating member 7 is disposed at the area surrounded by the bonding sections 511 of the first wires 51.

As shown in FIGS. 6 and 7, the maximum thickness of the coating member 7 is greater than the bonding section 511 of the first wire 51. As viewed in the z direction, the thickness of the coating member 7 is greater at the center than at the periphery. The maximum thickness of the coating member is preferably at least 20 μm, more preferably at least 80 μm, and even more preferably at least 160 μm. The thickness of the coating member 7 may vary depending on locations in a manner such that the coating member 7 has two portions of maximum value separated from each other in the y direction and has a portion of minimum value between the two portions.

As shown in FIG. 8, in the illustrated example, the coating member 7 includes a portion wedged between the first electrode 401 (the bulging section 4013) and the first face 5111 of the relevant bonding section 511. In other word, the coating member 7 includes a portion that surrounds the bonding section 511 below its largest diameter part.

As shown in FIG. 9, in the illustrated example, the coating member 7 includes a portion wedged between the first electrode 401 (the bulging section 4013) and the first face 61 of the metal lump 6. In other word, the coating member 7 includes a portion that surrounds the first face 61 below its largest diameter part.

The sealing resin 8 covers the first lead 1 and a part of each of the second leads 2 and the third leads 3, while also covering the semiconductor element 4, the first wires 51, the second wires 52, the metal lumps 6, and the coating member 7. The sealing resin 8 may be made of an insulating resin, such as epoxy resin mixed with fillers.

The shape of the sealing resin 8 is not limited. In the illustrated example, the sealing resin 8 has a resin obverse face 81, a resin reverse face 82, two first resin side faces 83, and two second resin side faces 84.

The resin obverse face 81 faces the same side in the z direction as the die pad obverse face 111, and may be flat.

The resin reverse face 82 faces opposite to the resin obverse face 81 in the z direction, and may be flat.

The two first resin side faces 83 are located between the resin obverse face 81 and the resin reverse face 82 in the z direction, and are arranged to face the opposite sides of the x direction, respectively. The two second resin side faces 84 are located between the resin obverse face 81 and the resin reverse face 82 in the z direction, and are arranged to face the opposite sides of the y direction, respectively.

Effects of the semiconductor device A1 may be as follows.

When operating the semiconductor element 4, at least a part of the energy generated by the electromotive force due to the current interruption converts into heat. The accumulation of the heat in the semiconductor element 4 may result in an excessively high temperature of the semiconductor element 4. The semiconductor device A1 includes the coating member 7 between the first electrode 401 and the sealing resin 8. The coating member 7 contains a material with higher thermal conductivity than the sealing resin 8. Hence, heat transfer from the first electrode 401 to the coating member 7 is promoted, so that an excessively high temperature in the semiconductor element 4 can be suppressed. Thus, the semiconductor device A1 can increase the energy absorbed by an active clamp.

In the case that the coating member 7 contains a metal, the heat transfer from the first electrode 401 is further promoted. In the case that the coating member 7 contains a metal, in particular Ag or Cu, the heat transfer across the coating member 7 is further promoted. In the case that the coating member 7 contains sintered Ag or sintered Cu, the desired shape of the coating member 7 can be obtained more reliably by emitting the material paste and then sintering the applied material paste.

In the case that the coating member 7 contains a metal, the coating member 7 is provided as a conductive member in contact with the first electrode 401. Thus, the conductive path from the switching section 408 to one of the first wires 51 can be provided by the coating member 7 in addition to the first electrode 401. Thus, the resistance of the semiconductor element 4 can be reduced.

The coating member 7 is in contact with the bonding section 511 of the first wires 51, so that a heat transfer path, which can mutually transfer heat between the coating member 7 and the first wires 51, is provided. Thus, the heat transferred to the coating member 7 can be released to the second leads 2 via the first wires 51.

In the case that the first electrode 401 contains Al and the coating member 7 contains sintered Ag, the bond between the first electrode 401 and the coating member 7 may not be strong enough. On the other hand, in the case that the first wires 51 contain Cu, the bond between the first electrode 401 and the first wires 51 and the bond between the first wires 51 and the coating member 7 are stronger than the bond between the first electrode 401 and the coating member 7. Hence, the separation of the coating member 7 from the first electrode 401 can be suppressed.

As shown in FIG. 8, in the present embodiment, the coating member 7 includes a portion wedged between the first electrode 401 (the bulging section 4013) and the first face 5111 of the bonding section 511. In other word, the coating member 7 includes a portion that surrounds the bonding section 511 below its largest diameter part. Thus, the separation of the coating member 7 can be further suppressed.

The semiconductor device A1 includes the metal lumps 6. The thermal conductivity of the metal lumps 6 is higher than the sealing resin 8. Hence, the energy absorbed by an active clamp can be further increased.

In the case that the first electrode 401 contains Al and the coating member 7 contains sintered Ag, the bond between the first electrode 401 and the coating member 7 may not be strong enough. On the other hand, in the case that the metal lumps 6 contain Cu, the bond between the first electrode 401 and the metal lumps 6 and the bond between the metal lumps 6 and the coating member 7 are stronger than the bond between the first electrode 401 and the coating member 7. Hence, the separation of the coating member 7 from the first electrode 401 can be suppressed.

As shown in FIG. 9, in the present embodiment, the coating member 7 includes a portion wedged between the first electrode 401 (the bulging section 4013) and the first face 61 of the metal lump 6. In other word, the coating member 7 includes a portion that surrounds the first face 61 below its largest diameter part. Thus, the separation of the coating member 7 can be further suppressed.

In the present embodiment, the bonding sections of the first wires 51 are arranged along the outer edge of the first electrode 401. The metal lumps 6 are arranged inward of the bonding section 511. Thus, when providing the coating section 7 after forming the first wires 51 and the metal lumps 6, it is possible to prevent the nozzle for applying the material paste from interfering with the first wires 51. It is also possible to prevent the material paste of the coating member 7 from unintentionally adhering to the first wires 51.

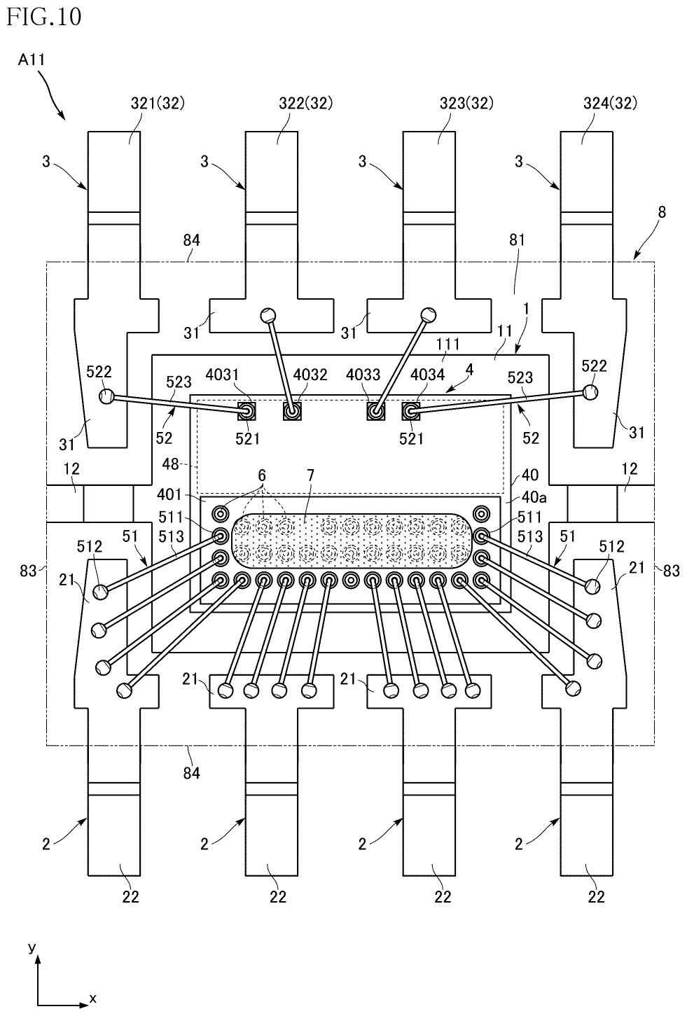

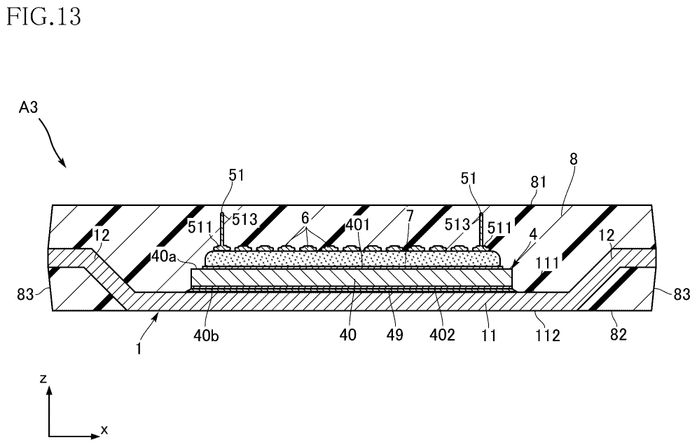

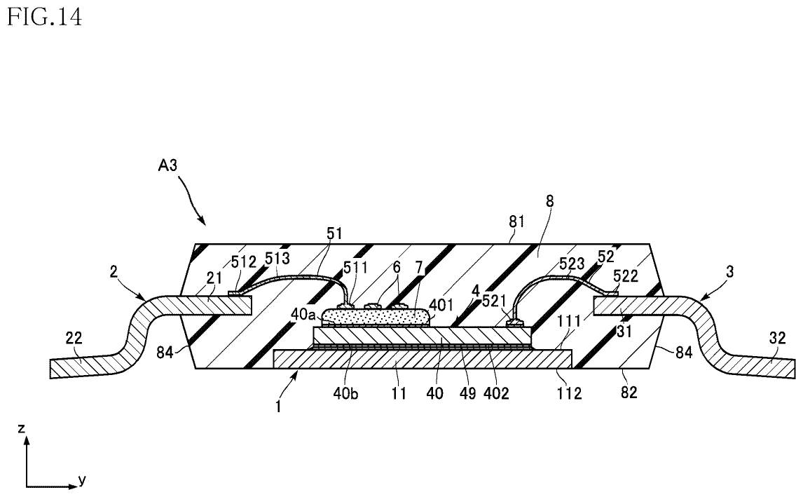

FIGS. 10-19 show variations and other embodiments of the present disclosure. In these figures, elements identical or similar to the above embodiment are labeled with the same symbols as in the above embodiment.

FIG. 10 shows a first variation of the semiconductor device A1. The semiconductor device A11 of the present variation differs from the above semiconductor device A1 in the area where the coating member 7 is provided.

In the present example, the coating member 7 is not in contact with the bonding sections 511 of the first wires 51, i.e., the coating member 7 is separated from the bonding sections 511 of the first wires 51 as viewed in the z direction. In other word, the bonding sections 511 are covered by the sealing resin 8 instead of the coating member 7. As with the semiconductor device A1, the coating member 7 covers most of the metal lumps 6.

In the present variation, the energy absorbed by an active clamp may be further increased. As understood from such a variation, the coating member 7 is not limited to being in contact with the first wires 51, but it may be in contact with the first electrode 401.

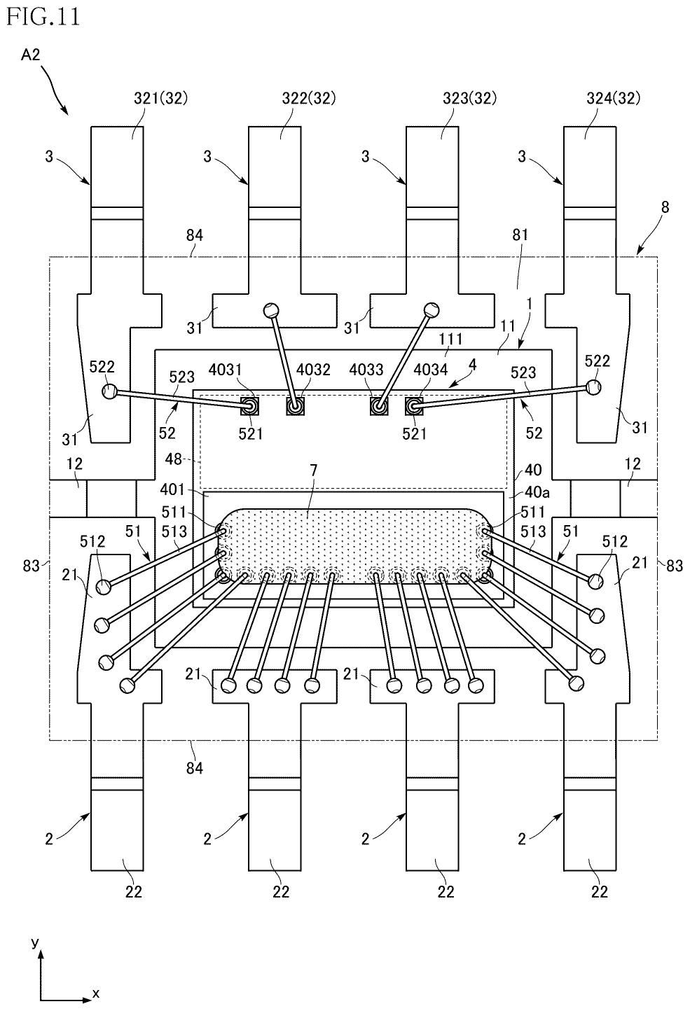

FIG. 11 shows a semiconductor device according to the second embodiment of the present disclosure. The semiconductor device A2 of the present embodiment differs from the above embodiment in that it includes no metal lumps 6.

In the present embodiment, the first electrode 401 is not joined with the metal lumps 6 but joined with the bonding sections 511 of the first wires 51. The contact area between the coating member 7 and the first electrode 401 is greater than that in the semiconductor device A1. The coating member 7 may be in contact with or disposed away from the bonding sections 511 of the first wires 51.

In the present embodiment, the energy absorbed by an active clamp may be further increased. As understood from the present embodiment, a semiconductor device according to the present disclosure may not include the metal lumps 6.

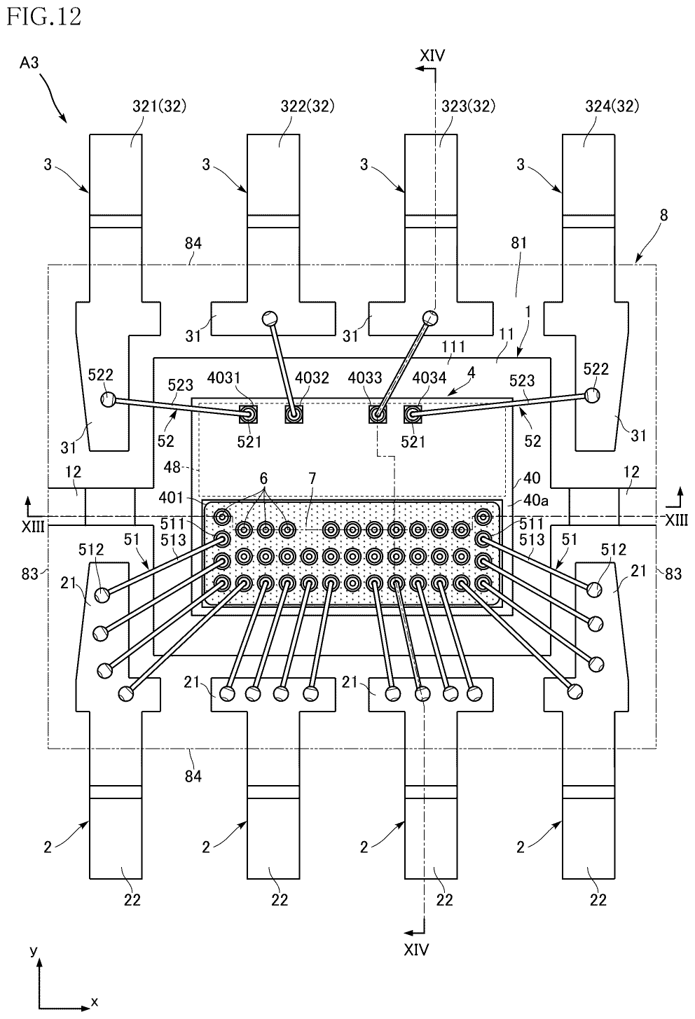

FIGS. 12-14 show a semiconductor device according to the third embodiment of the present disclosure. The semiconductor device A3 of the present embodiment differs from the above semiconductor device in the relationships among the first electrode 401, the first wires 51, the metal lumps 6, and the coating member 7.

In the present embodiment, the coating member 7 is interposed between the first electrode 401 and both of the metal lumps 6 and the bonding sections 511 of the first wires 51. In other word, the metal lumps 6 and the bonding sections 511 of the first wires 51 are provided on the coating member 7, and they are not in contact with the first electrode 401. The first wires 51 and the metal lumps 6 electrically conduct to the first electrode 401 through the coating member 7.

In the present embodiment, the bonding process of the first wires 51 and the formation of the metal lumps 6 may be performed after forming the coating member 7 on the first electrode 401.

In the present embodiment, the energy absorbed by an active clamp may be further increased. As understood from the present embodiment, the bonding sections 511 and the metal lumps 6 are not limited to being covered by the coating member 7, but they may be provided on the coating member 7.

In other embodiments below, the configurations of the bonding sections 511, the metal lumps 6 and the coating member 7 in the semiconductor devices A1, A11, A2, and A3 may be adopted in any suitable combination.

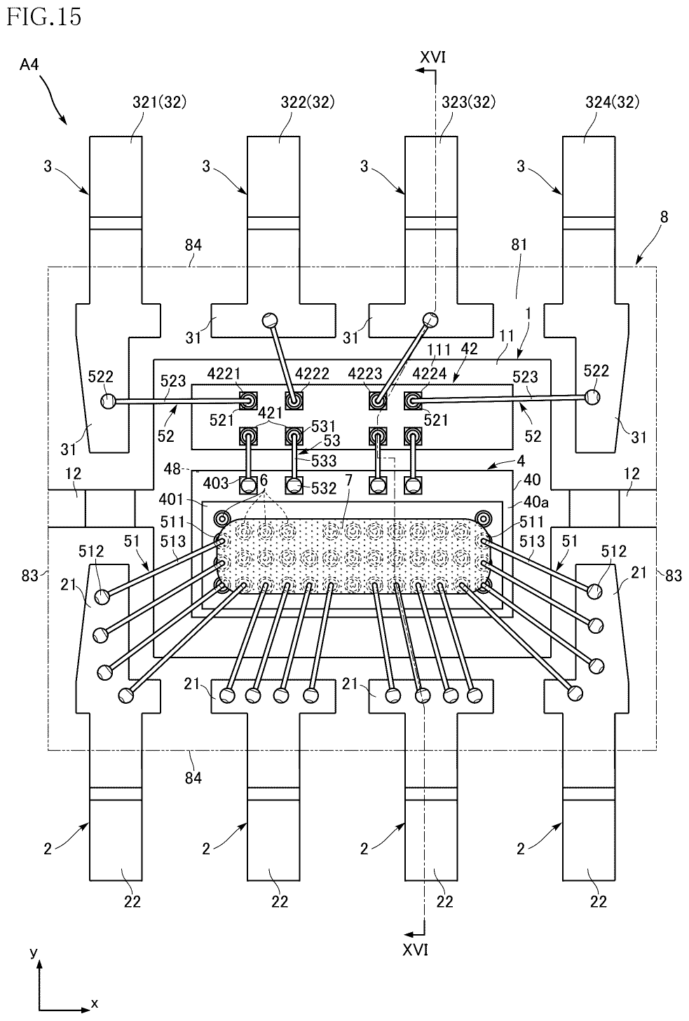

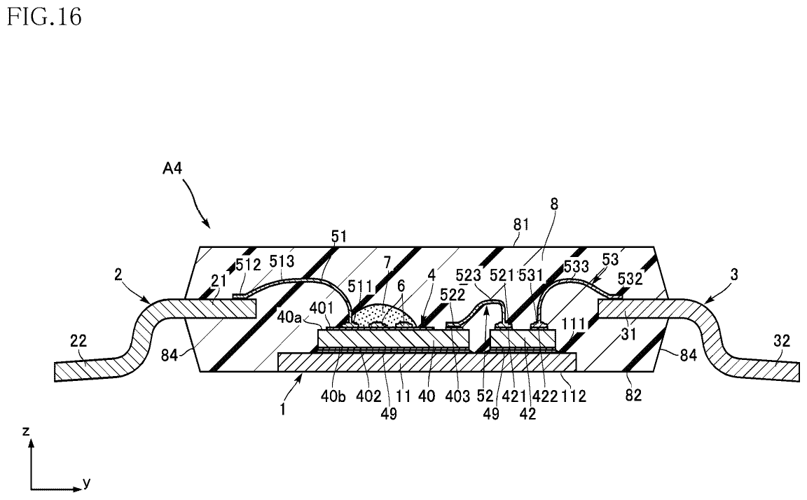

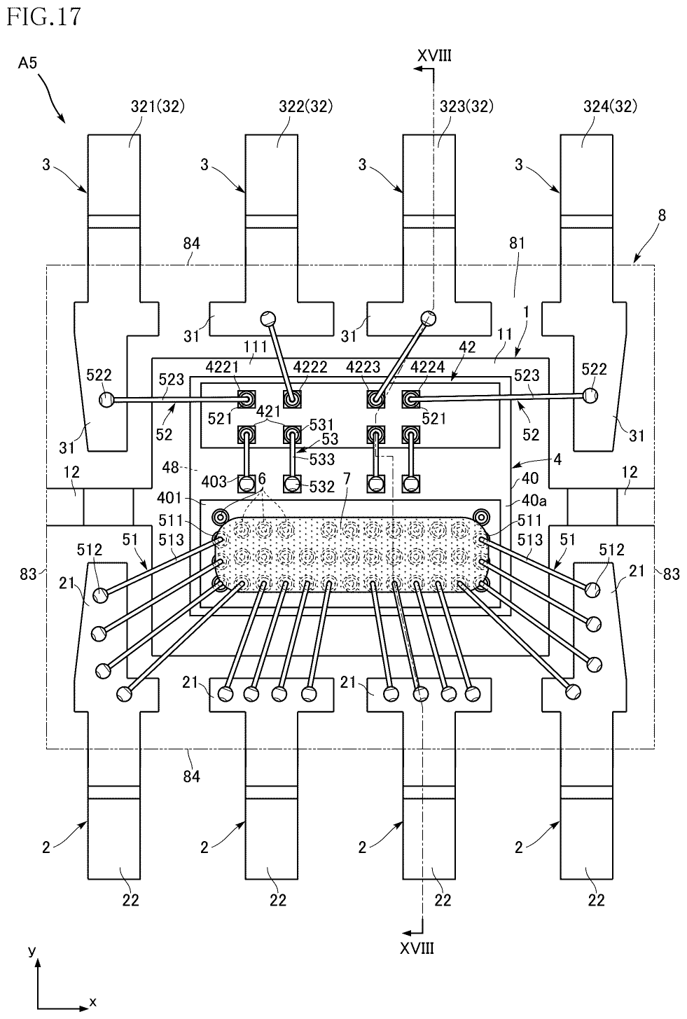

FIGS. 15-16 show a semiconductor device according to the fourth embodiment of the present disclosure. The semiconductor device A4 of the present embodiment differs from the above semiconductor devices in the configurations of the semiconductor element 4 and in that it includes a semiconductor element 42 and a plurality of third wires 53.

The semiconductor element 4 in the present embodiment includes the switching part 408, which performs switching, as in the above semiconductor devices, but does not include the control section 48.

The semiconductor element 42 has functions such as controlling, monitoring, and protecting the semiconductor element 4. The semiconductor element 4 and the semiconductor element 42 are each disposed on the die pad obverse surface 111 of the die pad section 11 via a bonding member 49. In the illustrated example, the semiconductor element 4 and the semiconductor element 42 are arranged side by side in the y direction.

The semiconductor element 42 includes a plurality of electrodes 421 and a plurality of electrodes 422. In the z direction, the electrodes 421 and the electrodes 422 are disposed in the same side. In the illustrated example, in the y direction, the electrodes 421 are disposed at the location closer to the semiconductor element 4. In the y direction, the electrodes 422 are disposed at the location closer to the third leads 3. The electrodes 422 include electrodes 4221, 4222, 4223, 4224. The electrode 4221 corresponds to the third electrode 4031 in the above semiconductor device A1. The electrode 4222 corresponds to the third electrode 4032 in the above semiconductor device A1. The electrode 4223 corresponds to the third electrode 4033 in the above semiconductor device A1. The electrode 4224 corresponds to the third electrode 4034 in the above semiconductor device A1.

In the present embodiment, the second wires 52 are individually connected to the electrodes 422 of the semiconductor element 42 and the third leads 3. In each wire, the bonding section 521 is joined to the electrode 422, and the bonding section 522 is joined to the pad section 31 of the third lead 3.

The semiconductor device A4 includes the third wires 53. The third wires 53 are individually connected to the third electrodes 403 of the semiconductor element 4 and the electrodes 421 of the semiconductor element 42. Each third wire 53 may include the bonding section 531, the bonding section 532, and the loop section 533 as with the second wire 52. In each wire, the bonding section 531 is joined to the third electrode 403, and the bonding section 532 is joined to the electrode 421.

In the present embodiment, the energy absorbed by an active clamp may be further increased. As understood from the present embodiment, the structure of the semiconductor element 4 is not limited. The die pad section 11 may support not only the semiconductor element 4 but also other semiconductor elements in addition to the semiconductor element 4, such as the semiconductor element 42. Moreover, the function of the semiconductor element other than the semiconductor element 4 is not limited.

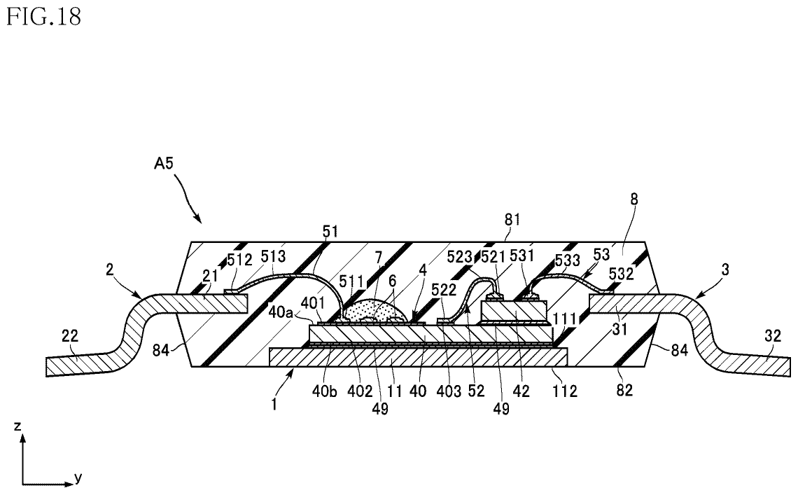

FIGS. 17 and 18 show a semiconductor device according to the fifth embodiment of the present disclosure. The semiconductor device A5 of the present embodiment includes the semiconductor element 4 and the semiconductor element 42 as with the semiconductor device A4.

In the present embodiment, the semiconductor element 42 is disposed on the element obverse face 40a of the semiconductor element 4. Specifically, the semiconductor element 42 is located opposite to the die pad section 11 with respect to the semiconductor element 4 in the z direction. The semiconductor element 42 and the semiconductor element 4 overlap with each other.

The semiconductor element 42 is joined to the element obverse face 40a of the semiconductor element 4 e.g., via the bonding member 49. In the illustrated example, as viewed in the z direction, the semiconductor element 42 is disposed at the location spaced apart from the first electrode 401 in the y direction. Unlike the illustrated example, the semiconductor element 42 may be disposed on the first electrode 401.

In the illustrated example, the first electrode 401 and the semiconductor element 42 each have a long rectangular shape whose longitudinal direction is the x direction. The third electrodes 403 are located between the first electrode 401 and the semiconductor element 42 in the y direction, and are located side by side in the x direction.

In the present embodiment, the energy absorbed by an active clamp may be also increased. As understood from the present embodiment, the position and the mounting configuration of the semiconductor element 42 are not limited.

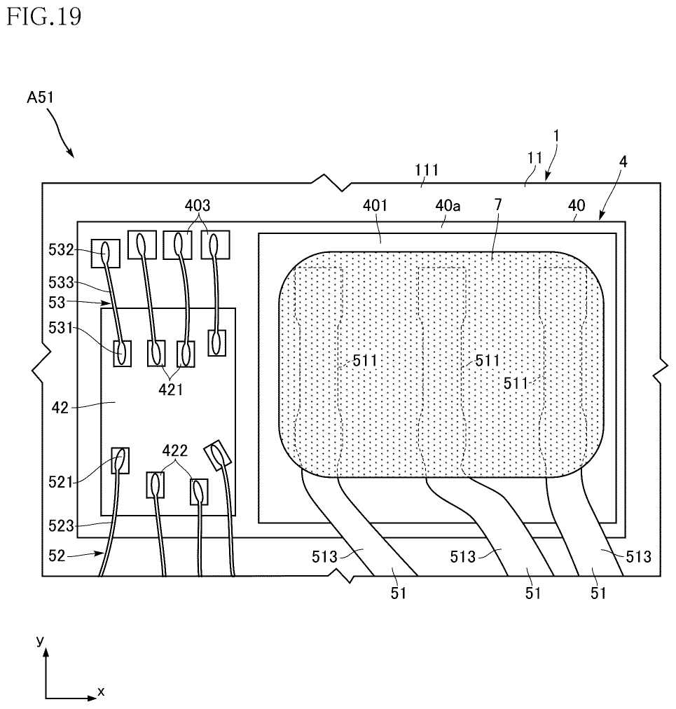

FIG. 19 shows a first variation of the semiconductor device A5. The semiconductor device A51 of the present variation differs from the above semiconductor device A5 in the specific configurations of the semiconductor element 4 and the semiconductor element 42. FIG. 19 partially shows the semiconductor device A51, i.e., the area where the semiconductor element 4, the semiconductor element 42, and a part of the die pad section 11 are located, with the sealing resin 8 omitted.

In the present example, the semiconductor element 42 is disposed on the element obverse face 40a of the semiconductor element 4. The semiconductor element 42 is disposed side by side with the first electrode 401 in the x direction.

The first wires 51 of the present example are provided by a wedge bonding method, for example. Each bonding section 511 extends in the y direction. The bonding sections 511 are arranged side by side in the x direction.

The semiconductor element 42 has a long rectangular shape whose longitudinal direction is the y direction. The third electrodes 403 of the semiconductor element 4 are located in one side of the y direction with respect to the semiconductor element 42, and are located side by side with each other in the x direction.

In such a variation, the energy absorbed by an active clamp may be also increased. As understood from such a variation, the position and the mounting configuration of the semiconductor element 42 are not limited.

The semiconductor devices according to the present disclosure are not limited to the embodiments described above. The specific configuration of each part of a semiconductor device according to the present disclosure may suitably be designed and changed in various manners. The present disclosure includes the embodiments described in the following clauses.

Clause 1. A semiconductor device comprising:
a semiconductor element including a first electrode;
a sealing resin covering the semiconductor element; and
a coating member;
wherein the coating member is interposed between the first electrode and the sealing resin, and contains a material with higher thermal conductivity than the sealing resin.

Clause 2. The semiconductor device according to clause 1, wherein the coating member contains a metal.

Clause 3. The semiconductor device according to clause 2, wherein the coating member contains Ag or Cu.

Clause 4. The semiconductor device according to clause 3, wherein the coating member contains sintered Ag or sintered Cu.

Clause 5. The semiconductor device according to any of clauses 1 to 4, wherein the first electrode contains Al.

Clause 6. The semiconductor device according to any of clauses 1 to 5, further comprising at least one first wire including a bonding section joined to the first electrode.

Clause 7. The semiconductor device according to clause 6, wherein the at least one first wire includes a plurality of first wires, and the bonding sections of the plurality of first wires are disposed along an outer edge of the first electrode.

Clause 8. The semiconductor device according to clause 7, wherein the coating member is disposed at an area surrounded by the bonding sections of the plurality of first wires.

Clause 9. The semiconductor device according to any of clauses 6 to 8, wherein each first wire contains a metal different from a metal contained in the first electrode.

Clause 10. The semiconductor device according to any of clauses 6 to 9, wherein each first wire contains Cu.

Clause 11. The semiconductor device according to any of clauses 6 to 10, wherein the coating member is in contact with the bonding section of each first wire.

Clause 12. The semiconductor device according to any of clauses 6 to 11, further comprising at least one metal lump joined to the first electrode.

Clause 13. The semiconductor device according to clause 12 wherein the metal lump contains a metal different from a metal contained in the first electrode.

Clause 14. The semiconductor device according to clause 12 or 13, wherein the coating member is in contact with the metal lump.

Clause 15. The semiconductor device according to clause 14, wherein the coating member covers the metal lump.

Clause 16. The semiconductor device according to clause 15 wherein a maximum thickness of the coating member is greater than a thickness of the bonding section of each first wire.

Clause 17. The semiconductor device according to clause 15 or 16, wherein the coating member includes a periphery and a center portion that is thicker than the periphery.

Clause 18. The semiconductor device according to any of clauses 15 to 17, wherein the maximum thickness of the coating member is at least 20 μm.

Clause 19. The semiconductor device according to any of clauses 15 to 17, wherein the maximum thickness of the coating member is at least 80 μm.

Clause 20. The semiconductor device according to any of clauses 15 to 17, wherein the maximum thickness of the coating member is at least 160 μm.

Clause 21. The semiconductor device according to any of clauses 15 to 20, wherein the metal lump is disposed opposite to the outer edge of the first electrode with respect to the bonding section of each first wire.

Clause 22. The semiconductor device according to clause 21, wherein each first wire has a loop section connected to the bonding section, and
the loop section extends outwardly of the semiconductor element and intersects the outer edge of the first electrode in plan view.

Clause 23. The semiconductor device according to any of clauses 15 to 22, wherein the metal lump includes a first face facing the first electrode and being inclined so as to be located further away from a center of the metal lump as proceeding further away from the first electrode,
the coating member includes a portion between the first electrode and the first face.

Clause 24. The semiconductor device according to any of clauses 1 to 23, wherein the semiconductor element includes a switching section to perform switching and a control section to control the switching section, and
the first electrode is an electrode of the switching section.

Clause 25. The semiconductor device according to clause 24, wherein the first electrode is a source electrode.

REFERENCE NUMERALS

| | | |
|---|---|---|
| A1, A11, A2, A3, A4, A5, A51: Semiconductor device | | |
| 1: First lead | 2: Second lead | 3: Third lead |
| 4: Semiconductor element | 6: Metal lump | 7: Coating member |
| 8: Sealing resin | 11: Die pad section | 12: Extending section |
| 21: Pad section | 22: Terminal section | 31: Pad section |
| 32: Terminal section | 40: Element body | |
| 40a: Element obverse face | 40b: Element reverse face | |
| 42: Semiconductor element | 48: Control section | |
| 49: Bonding member | 51: First wire | 52: Second wire |
| 53: Third wire | 61: First face | 62: Second face |
| 63: Projection | 81: Resin obverse face | |
| 82: Resin reverse face | 83: First resin side face | |
| 84: Second resin side face | 111: Die pad obverse face | |
| 112: Die pad reverse face | 401: First electrode | |
| 402: Second electrode | | |
| 403, 4031, 4032, 4033, 4034: Third electrode | | |
| 408: Switching section | | |
| 421, 422, 4221, 4222, 4223, 4224: Electrode | | |
| 511, 512, 521, 522, 531, 532: Bonding section | | |
| 513, 523, 533: Loop section | 4011: Base thickness section | |
| 4012: Reduced thickness section | 4013: Bulging section | |
| 5111: First face | 5112: Second face | |

1. A semiconductor device comprising:
a semiconductor element including a first electrode;
a sealing resin covering the semiconductor element; and
a coating member;
wherein the coating member is interposed between the first electrode and the sealing resin, and contains a material with higher thermal conductivity than the sealing resin.

2. The semiconductor device according to claim 1, wherein the coating member contains a metal.

3. The semiconductor device according to claim 2, wherein the coating member contains Ag or Cu.

4. The semiconductor device according to claim 3, wherein the coating member contains sintered Ag or sintered Cu.

5. The semiconductor device according to claim 1, wherein the first electrode contains Al.

6. The semiconductor device according to claim 1, further comprising at least one first wire including a bonding section joined to the first electrode.

7. The semiconductor device according to claim 6, wherein the at least one first wire includes a plurality of first wires, and
the bonding sections of the plurality of first wires are disposed along an outer edge of the first electrode.

8. The semiconductor device according to claim 7, wherein the coating member is disposed at an area surrounded by the bonding sections of the plurality of first wires.

9. The semiconductor device according to claim 6, wherein each first wire contains a metal different from a metal contained in the first electrode.

10. The semiconductor device according to claim 6, wherein each first wire contains Cu.

11. The semiconductor device according to claim 6, wherein the coating member is in contact with the bonding section of each first wire.

12. The semiconductor device according to claim 6, wherein further comprising at least one metal lump joined to the first electrode.

13. The semiconductor device according to claim 12 wherein the metal lump contains a metal different from a metal contained in the first electrode.

14. The semiconductor device according to claim 12, wherein the coating member is in contact with the metal lump.

15. The semiconductor device according to claim 14, wherein the coating member covers the metal lump.

16. The semiconductor device according to claim 15 wherein a maximum thickness of the coating member is greater than a thickness of the bonding section of each first wire.

17. The semiconductor device according to claim 15, wherein the coating member includes a periphery and a center portion that is thicker than the periphery.

18. The semiconductor device according to claim 15, wherein the maximum thickness of the coating member is at least 20 μm.

19. The semiconductor device according to claim 15, wherein the maximum thickness of the coating member is at least 80 μm.

20. The semiconductor device according to claim 15, wherein the maximum thickness of the coating member is at least 160 μm.
